(19) United States
(12) Patent Application Publication
(10) Pub. No.: US 2025/0209221 A1
(43) Pub. Date: Jun. 26, 2025

(54) SYSTEMS AND METHODS THAT INCLUDE STANDARD CELL YIELD PREDICTIONS IN A LIBRARY

(71) Applicant: Intel Corporation, Santa Clara, CA (US)

(72) Inventors: Srikanth Venkat Raman, Hillsboro, OR (US); Pascal A. Meinerzhagen, Muri bei Bern (CH); Andrew Radcliffe, Beaverton, OR (US); Jimmy Voong Liu, Hillsboro, OR (US); Jay Gandhi, Manikonda (IN); Muhammad M. Khellah, Tigard, OR (US)

(73) Assignee: Intel Corporation, Santa Clara, CA (US)

(21) Appl. No.: 18/394,596

(22) Filed: Dec. 22, 2023

(51) Int. Cl. G06F 30/10

(52) U.S. Cl. CPC G06F 30/10

(57) ABSTRACT

Systems and methods for providing standard cell yield information in a library (i.e., creating “defect-aware” libraries). The method includes accessing a library of a plurality of standard cells characterized on a foundry process node and revision. A geometric analysis is performed on individual ones of the standard cells to identify potential defects, such as shorts and opens. A defect is injected (i.e., “realized” or “actualized”) at the location of the identified potential defects. The standard cells in the library are then simulated with the defects injected to generate simulated yield information. Additionally, methods can access silicon failure analysis data representing test chips designed with the library and generate an inferred failure rate for the individual standard cells in the library, as a function of the silicon failure analysis and the simulated yield information.

### BACKGROUND

Electronic Design Automation (EDA) tools, such as placement, synthesis, and routing tools, often utilize third-party libraries, and circuit designers use the EDA tools to design a product, such as a complex integrated circuit intellectual property (IP) design and/or system on chip (SoC).

The third-party libraries include performance characteristics for a target foundry process and version/release. However, the process/version can have inherent issues that are not discovered until the product gets tested. Therefore, it is desirable for libraries to provide improved standard cell performance predictions.

### BRIEF DESCRIPTION OF THE DRAWINGS

FIG. 1 is a block diagram depicting an example environment in which embodiments may operate.

FIG. 2 provides a non-limiting example of architectural block diagram of one or more application modules that may be operating in the system that include standard cell yield predictions in a library, in accordance with various embodiments.

FIG. 3 illustrates process steps of a method that include standard cell yield predictions in a library, in accordance with various embodiments.

FIG. 4 is a top view of a wafer and dies that may have at least one embedded DTC component, in accordance with any of the embodiments disclosed herein.

FIG. 5 is a simplified cross-sectional side view showing an implementation of an integrated circuit on a die that may include various embodiments, in accordance with any of the embodiments disclosed herein.

FIG. 6 is a cross-sectional side view of a microelectronic assembly that may include any of the embodiments disclosed herein.

FIG. 7 illustrates an exemplary compute node, on which embodiments may operate.

### DETAILED DESCRIPTION

Third-party libraries comprise intellectual property (IP) cores, which are reusable units of logic and/or layout for standard cells. As is understood by those with skill in the art, a standard cell is a function in digital logic, it can be a simple function, like an inverter, or a more complex gate or sequential element. The third-party libraries include geometries and margins, for example, the length, width, and thickness of a metal trace or gate, and its margin, such as +/−20%. Further, third-party libraries are characterized by (i.e., they include performance characteristics for) a target foundry process and version/release.

Many Electronic Design Automation (EDA) tools, such as placement, synthesis, and routing tools, utilize the third-party libraries (referred to as “libraries” herein) for process-specific information to enable circuit designers to design a product to be manufactured on a target process. Non-limiting examples of such products include complex integrated circuit intellectual property (IP) designs and/or systems on chip (SoC).

However, the process/version can have inherent issues that are not discovered until the product is fabricated and tested, such as, during failure analysis. A product may not be functional or may have a low yield using a given third-party library because of a standard cell defect that occurs because of a manufacturing issue rather than due to a faulty design. Additionally, each time a change is made to a process node or version, a corresponding new third-party library may be released. In a non-limiting example, a process node may have a lifespan of several years but go through a few revisions/versions during its lifespan. These new releases can adversely affect the product yield in this same modality.

For at least the above reasons, there are technical challenges related to third-party libraries and their use in EDA tools. Therefore, it is desirable for the libraries to be improved, which will enable EDA tools to deliver improved performance predictions (e.g., speed and power consumption) in an earlier phase of design (e.g., right at synthesis) for circuit designers. This is especially desirable in the designs of large IP products using thousands of standard cells, such as an entire graphics units, etc.

Embodiments provide a technical solution to this technical problem and other related enhancements, in the form of systems and methods for providing standard cell yield information in a library (i.e., “defect-aware” libraries). Some embodiments implement machine learning (ML) or artificial intelligence (AI) to perform some of the processing described herein.

Aspects of this disclosure can be detected with a visual inspection of release notes from third-party suppliers of libraries, the release notes would accompany a process node and/or process node revision release. If the release notes reference or supply yield measures along with standard power-performance and variation characterization data, this can indicate the presence of the herein disclosed embodiments. Additionally, the EDA tools themselves may use the herein disclosed embodiments. EDA tool use can be determined if the user guides or documentation for the EDA tool refers to flows for defect injection, defect simulation, silicon learning and/or AI/ML-model based modeling/prediction of standard cells yield, that would indicate potential infringement. A more detailed description of the aspects of the present disclosure follows a terminology section.

### Terminology

As used herein, a “computing system” or “compute device” refers to any of a variety of computing devices and includes systems comprising multiple discrete physical components. In some embodiments, the computing systems are located in laptop computer, a desktop computer, a data center, such as an enterprise data center (e.g., a data center owned and operated by a company and typically located on company premises), managed services data center (e.g., a data center managed by a third party on behalf of a company), a collocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

As used herein, the terms “processor unit”, “processing unit” or “processor” may refer to any device or portion of a device that processes electronic data from registers and/or memory to transform that electronic data into other electronic data that may be stored in registers and/or memory. A processor unit may be a system-on-a-chip (SOC), and/or include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

For the sake of brevity, conventional techniques related to signal processing, data transmission, signaling, control, machine learning models, radar, lidar, image analysis, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

### DESCRIPTION OF ASPECTS OF THE PRESENT DISCLOSURE

Example embodiments are hereinafter described in conjunction with the following drawing figures, wherein like numerals denote like elements. Figures are not necessarily to scale. As may be appreciated, certain terminology, such as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe an orientation and/or location within a consistent but arbitrary frame of reference which is made clear by reference to the text and the associated Figures describing the component under discussion. Such terminology may include the words specifically mentioned above, derivatives thereof, and words of similar import. For the sake of brevity, well-known structures and devices may be shown in block diagram form to facilitate a description thereof.

Embodiments of systems that include standard cell yield prediction in a library/defect-aware design automation may be implemented in a variety of systems, apparatus, consumer products, such as electronic design automation (EDA) tools, computer aided design (CAD) tools, computing devices, and the like. Additionally, embodiments of systems that include standard cell yield prediction in a library/defect-aware design automation can be found in machine-readable storage media having machine-readable instructions that when executed cause one or more processor to perform a method as described herein.

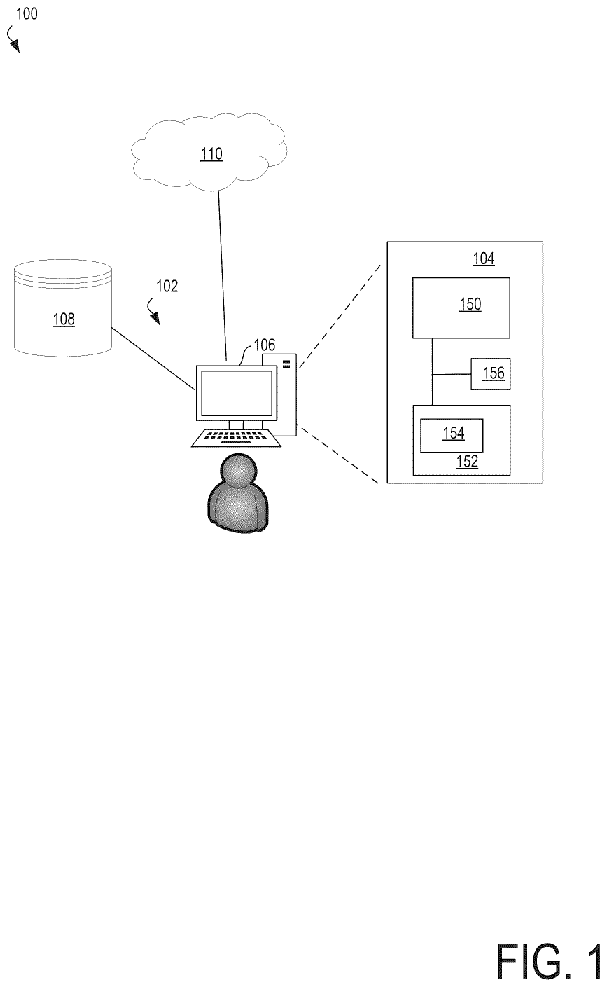

FIG. 1 illustrates an exemplary environment 100 in which embodiments may operate. The system that includes standard cell yield prediction in a library/defect-aware design automation (shortened herein to system 102) may operate on a compute device 106 and be in wire or wireless communication with one or more database(s) 108, and in wireless communication with the cloud 110. The system 102 includes a control module.

As used herein, the term “module” may refer to any hardware, software, firmware, electronic control component, processing logic, and/or processor device, individually or in any combination. In various embodiments, a module is one or more of: an application specific integrated circuit (ASIC), a field-programmable gate-array (FPGA), an electronic circuit, a computer system comprising a processor (shared, dedicated, or group) and memory that executes one or more software or firmware programs, a combinational logic circuit, and/or other suitable components that provide the functionality attributed to the module. In various embodiments, a software program in a module encodes an algorithm or procedure of rules for the processor to execute. In various embodiments, all or part of the functionality of the control module can be performed by a machine learning model (ML), neural net (NN) or other variation of artificial intelligence.

In FIG. 1, the control module is embodied as a control circuit 104. In various embodiments, the control circuit 104 is realized as an enhanced computer system, comprising a computer readable storage device or media, memory 152, for storage of instructions, algorithms, and/or programs, such as vehicle-target localization algorithm and a plurality of preprogrammed thresholds and parameters, the processor 150 to execute the program 154, and input/output interface (I/O) 156. The computer readable storage device or media, memory 152, may include volatile and nonvolatile storage in read-only memory (ROM), random-access memory (RAM), and keep-alive memory (KAM), for example. KAM is a persistent or non-volatile memory that may be used to store various operating variables while the processor 150 is powered down. The memory 152 may be implemented using any of a number of known memory devices such as PROMs (programmable read-only memory), EPROMS (electrically PROM), EEPROMs (electrically erasable PROM), flash memory, or any other electric, magnetic, optical, or combination memory devices capable of storing data, some of which represent executable instructions, used by the processor 150 in controlling the system 102. In various embodiments, processor 150 is configured to implement the system 102. The memory 152 may also be utilized by the processor 150 to cache data, to temporarily store results of comparisons and analyses, and the like. Information in the memory 152 may be organized and/or imported from an external source during an initialization or installment operation in a method; it may also be programmed via a user I/O interface.

The input/output interface (I/O) 156 may be operationally coupled to the processor 150 via a bus and enables intra-control circuit 104 communication as well as extra-control circuit 104 communication. The input/output interface (I/O) 156 may include one or more wired and/or wireless network interfaces and can be implemented using any suitable method and apparatus. In various embodiments, the input/output interface (I/O) 156 includes the hardware and software to support one or more communication protocols for wireless communication between the processor 150 and external sources, such as satellites, the cloud, communication towers and ground stations. In various embodiments, the input/output interface (I/O) 156 supports communication with technicians, and/or one or more storage interfaces for direct connection to storage apparatuses.

During operation of the system 102, the processor 150 loads and executes one or more algorithms, instructions, and rules embodied as program 154, and, as such, controls the general operation of the system 102. During operation of the system 102, the processor 150 may receive data from external sources (such as WiFi signal(s), the cloud 110, or other systems configured to operate within the computing device 106). In various embodiments of the system 102, the control circuit 104 may: perform operations attributed to the system 102 in accordance with an algorithm; perform operations in accordance with state machine logic; and perform operations in accordance with logic in a programmable logic array.

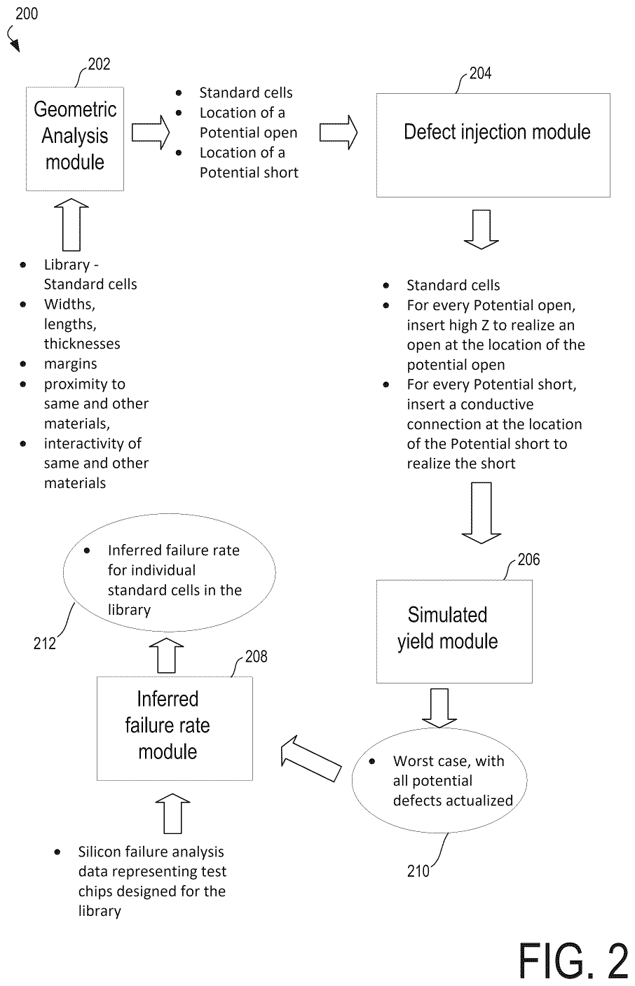

While the exemplary embodiment of the system 102 is described in the context of the control circuit 104 implemented as a fully functioning enhanced computer system, those skilled in the art will recognize that the mechanisms of the present disclosure are capable of being distributed as a program product including program 154 and predefined parameters. Such a program product may comprise an arrangement of instructions organized as multiple interdependent program code modules (see, e.g., FIG. 2, 200), each configured to achieve a separate process and/or perform a separate algorithmic operation, arranged to manage data flow through the system 102. The program code modules may each comprise an ordered listing of executable instructions for implementing logical functions for the processes performed by the system 102. The instructions in the program code modules, when executed by a processor (e.g., processor 150), cause the processor to receive and process signals, and perform logic, calculations, methods and/or algorithms as described herein for automatically and in real-time performing vehicle-target localization and generating associated commands.

Once developed, the program code modules constituting a program product may be stored and distributed individually, or together, using one or more types of non-transitory computer-readable signal bearing media may be used to store and distribute the instructions, such as a non-transitory computer readable medium. Such a program product may take a variety of forms, and the present disclosure applies equally regardless of the type of computer-readable signal bearing media used to carry out the distribution. Examples of signal bearing media include recordable media such as floppy disks, hard drives, memory cards and optical disks, and transmission media such as digital and analog communication links. It will be appreciated that cloud-based storage and/or other techniques may also be utilized as memory and as program product time-based viewing of clearance requests in certain embodiments.

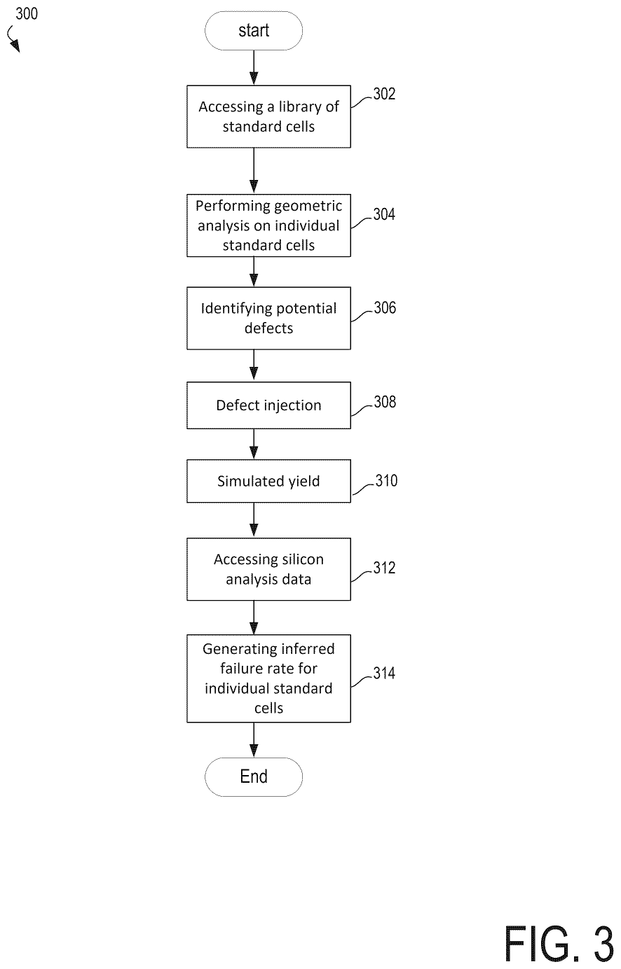

FIG. 2 and FIG. 3 can be referenced together. FIG. 2 provides a non-limiting example embodiment 200 of the system 102 showing an architectural block diagram of one or more application modules (e.g., the aforementioned interdependent program code modules) that may be operating in the system 102. The modules in FIG. 2 are referenced in conjunction with FIG. 3, which illustrates process steps of a method 300 that include standard cell yield predictions in a library.

The system 102 receives or accesses the library of a plurality of standard cells. Individual of the standard cells can comprise both a circuit embodiment and a layout embodiment. The standard cell layout embodiments include geometry for fabrication layers, such as lengths, widths, thicknesses, for metal traces, gates, sources, drains, contacts, power traces, ground traces, and the like. There can also be proximity rules or pitch, meaning a distance between two features, and between materials (e.g., a contact metal and a nearby contact trace). In addition, geometry and pitch can have an associated margin. In a non-limiting example, a gate length can be 7 nanometers plus or minus 1 nanometer (alternatively, plus or minus 10%, or plus or minus 20%). The individual standard cells are characterized for the foundry process node and process node revision, which means they also have predicted operational switching speeds and power consumption, etc., expected based on fabricating them on the foundry process node and process node revision.

At 304, the system 102 may, for individual ones of the plurality of standard cells, perform a geometric analysis on said individual ones of the plurality of standard cells, and at 306, identify one or more potential defects based on the geometric analysis. In an embodiment of the system 102, to perform at 304, a geometric analysis module 202 may access (at 302) the library comprising a plurality of standard cells, wherein the library is characterized on a foundry process node and process node revision.

As mentioned, potential defects can include an open (circuit) and/or a short (circuit). After geometric analysis at 304, the locations that are vulnerable to a potential defect are located in the entire library, the type of potential defect (open/short) is known, and the location of individual of the potential defect is also known. Individual cells may have zero potential defects, one potential defect, or one or more potential defects. Accordingly, upon completion of the geometric analysis of the entire library of standard cells at 304, there may be one or more potential defects for the library.

At 308, a defect injection process may be implemented, defined as, in response to the determinations made at 304: for every potential open, insert a high impedance to realize or inject the open defect at the location of the potential open; and, for every potential short, insert a highly conductive connection at the location of the potential short to realize or inject the short defect at the location of the potential short. In an embodiment of the system 102, a defect injection module 204 in the system 102 may comprise the program code or circuitry to perform the defect injection process at 308.

At 310, the system 102 may simulate the operation of individual standard cells in the library to generate simulated yield information for the library on the foundry process node and the process node revision, based on implementation of the defect injection process. In an embodiment of the system 102, a simulated yield module 206 performs these operations. As those with skill will realize, after the defect injection process at 308, the standard cells are revised to perform at the worst margin on the foundry process node and node revision; therefore, the simulated yield information 210 can provide a worst-case scenario, reflecting a scenario in which every potential defect manifests as an actual defect (i.e., a defect rate of 100%).

The output simulated yield information 210 from 310 is independently useful, and in addition, those with skill in the art will realize that the standard cells modified as they were at 308 may not always cause a design failure in every silicon product, and further, that every potential defect may not always occur in a silicon product (i.e., an actual defect rate may be less than that determined at 310. In some cases, the defects that are present may only cause a performance (speed, power consumption) degradation.

Accordingly, in various embodiments, the system 102 is configured to generate an inferred failure rate 212 for individual standard cells in the library, using actual silicon failure analysis results, as follows. At 312, the system 102 may receive or accept as input silicon failure analysis data representing a plurality of die that are all the same product test chip, the test chip having been designed for the library. Said differently, the product test chip was designed (synthesized) with the library of standard cells characterized for the foundry process node and process node revision. The silicon failure analysis may have been failure analysis performed on a wafer level (i.e., on un-singulated die). As those with skill in the art will appreciate, the silicon failure analysis provides one view (e.g., a first view) of an actual rate of failure of the identified potential defects (whereas the simulated yield information 210 represents all defects being present, or completely defect-aware results). In embodiment 200 this processing may be performed by an inferred failure rate module 208.

At 314, the system 102 may generate the inferred failure rate 212 for individual standard cells, as a function of the silicon failure analysis and the simulated yield information 210. After 314 the method may end, or it may access additional data.

In an example, after 314, the system 102 accesses new silicon failure analysis data representing a different plurality of test chips designed with the library. In other words, the new silicon data represents failure analysis on a second test chip and comprises data from a plurality of the second test chips. The system 102 is configured to revise the inferred failure rate 212 for the individual standard cells responsive to the new silicon failure analysis data. This cycle can be repeated multiple times.

Alternatively, after 314, a new library can be released that represents either (1) a revised foundry process node, (2) a process node revision, or (3) both (i.e., (1) and (2)). In response to the new library, the system 102 may return to (at 304) performing geometric analysis and proceed through the process flow of method 300 therefrom.

In various embodiments, a portion of the system 102, such as, the inferred failure rate module 208, is configured as a machine learning (ML) model. As a ML model, the inferred failure rate module 208 can be trained on input data, wherein each block of input data comprises silicon failure analysis data from a plurality of a same design product test chip. In other words, if three product test chips are designed for the library, each of the three would be fabricated into a respective plurality of die on a respective wafer, resulting in a respective 3 different silicon failure analysis data inputs, in sequence, at 312.

Thus, systems and methods that include standard cell yield predictions in a library have been provided. Embodiments are defect-aware in that they determine a worst-case simulated yield information 210, and can be revised or trained to provide improved inferred failure rates for individual standard cells in the library for a foundry process node and process node revisions. The following description illustrates various context for usage and application of provided aspects of the present disclosure.

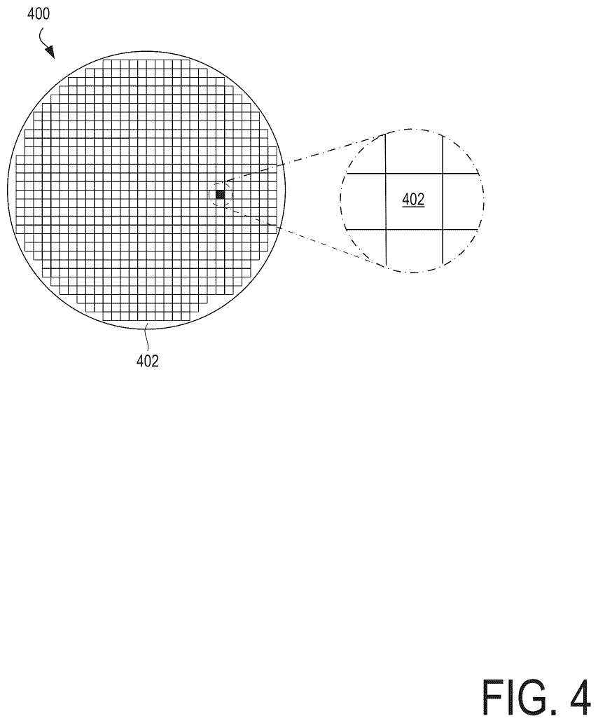

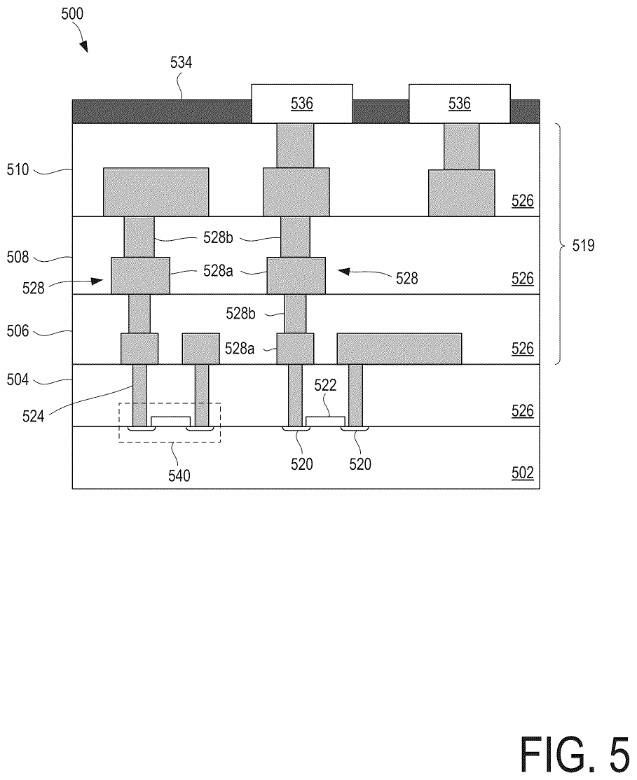

FIG. 4 is a top view of a wafer 400 and dies 402 that may be include any of the embodiments disclosed herein. The wafer 400 may be composed of semiconductor material and may include one or more dies 402 formed on a surface of the wafer 400. After the fabrication of the integrated circuit components on the wafer 400 is complete, the wafer 400 may undergo a singulation process in which the dies 402 are separated from one another to provide discrete “chips” or destined for a packaged integrated circuit component. The individual dies 402, comprising an integrated circuit component, may include one or more transistors (e.g., some of the transistors 540 of FIG. 5, discussed below), supporting circuitry to route electrical signals to the transistors, passive components (e.g., signal traces, resistors, capacitors, or inductors), and/or any other integrated circuit components. In some embodiments, the wafer 400 or the die 402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 402. For example, a memory array formed by multiple memory devices may be formed on a same die 402 as a processor unit or other logic that is configured to store information in the memory devices or execute instructions stored in the memory array. In some embodiments, a die 402 may be attached to a wafer 400 that includes other die, and the wafer 400 is subsequently singulated, this manufacturing procedure is referred to as a die-to-wafer assembly technique.

FIG. 5 is a cross-sectional side view of an integrated circuit 500 that may be included in any of the embodiments disclosed herein. One or more of the integrated circuits 500 may be included in one or more dies 402 (FIG. 4). The integrated circuit 500 may be formed on a die substrate 502 (e.g., the wafer 400 of FIG. 4) and may be included in a die (e.g., the die 402 of FIG. 4).

The die substrate 502 may be a semiconductor substrate composed of semiconductor material systems including, for example, n-type or p-type materials systems (or a combination of both). The die substrate 502 may include, for example, a crystalline substrate formed using a bulk silicon or a silicon-on-insulator (SOI) substructure. In some embodiments, the die substrate 502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit 500 may be used. The die substrate 502 may be part of a singulated die (e.g., the dies 402 of FIG. 4) or a wafer (e.g., the wafer 400 of FIG. 4).

The integrated circuit 500 may include one or more device layers 504 disposed on the die substrate 502. The device layer 504 may include features of one or more transistors 540 (e.g., metal oxide semiconductor field-effect transistors (MOSFETs)) formed on the die substrate 502. The transistors 540 may include, for example, one or more source and/or drain (S/D) regions 520, a gate 522 to control current flow between the S/D regions 520, and one or more S/D contacts 524 to route electrical signals to/from the S/D regions 520.

The gate 522 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 540 along the source-channel-drain direction, the gate electrode may comprise a U-shaped structure that includes a bottom portion substantially parallel to the surface of the die substrate 502 and two sidewall portions that are substantially perpendicular to the top surface of the die substrate 502. In other embodiments, at least one of the metal layers that form the gate electrode may simply be a planar layer that is substantially parallel to the top surface of the die substrate 502 and does not include sidewall portions substantially perpendicular to the top surface of the die substrate 502. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of individual transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be conducted to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 5 as interconnect layers 506-510). For example, electrically conductive features of the device layer 504 (e.g., the gate 522 and the S/D contacts 524) may be electrically coupled with the interconnect structures 528 of the interconnect layers 506-510. The one or more interconnect layers 506-510 may form a metallization stack (also referred to as an “ILD stack”) 519 of the integrated circuit 500.

The interconnect structures 528 may be arranged within the interconnect layers 506-510 to route electrical signals according to a wide variety of designs; in particular, the arrangement is not limited to the particular configuration of interconnect structures 528 depicted in FIG. 5. Although a particular number of interconnect layers 506-510 is depicted in FIG. 5, embodiments of the present disclosure include integrated circuits having more or fewer interconnect layers than depicted.

In some embodiments, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page. The vias 528b may be arranged to route electrical signals in a direction of a plane that is substantially perpendicular to the surface of the die substrate 502 upon which the device layer 504 is formed. In some embodiments, the vias 528b may electrically couple lines 528a of different interconnect layers 506-510 together.

The interconnect layers 506-510 may include a dielectric material 526 disposed between the interconnect structures 528, as shown in FIG. 5. In some embodiments, dielectric material 526 disposed between the interconnect structures 528 in different ones of the interconnect layers 506-510 may have different compositions; in other embodiments, the composition of the dielectric material 526 between different interconnect layers 506-510 may be the same. The device layer 504 may include a dielectric material 526 disposed between the transistors 540 and a bottom layer of the metallization stack as well. The dielectric material 526 included in the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (referred to as Metal 1 or “M1”) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. The vias 528b of the first interconnect layer 506 may be coupled with the lines 528a of a second interconnect layer 508.

The second interconnect layer 508 (referred to as Metal 2 or “M2”) may be formed directly on the first interconnect layer 506. In some embodiments, the second interconnect layer 508 may include via 528b to couple the lines of the interconnect structures 528 of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (referred to as Metal 3 or “M3”) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit 500 (i.e., farther away from the device layer 504) may be thicker that the interconnect layers that are lower in the metallization stack 519, with lines 528a and vias 528b in the higher interconnect layers being thicker than those in the lower interconnect layers.

The integrated circuit 500 may include a solder resist material 534 (e.g., polyimide or similar material) and one or more conductive contacts 536 formed on the interconnect layers 506-510. In FIG. 5, the conductive contacts 536 are illustrated as taking the form of bond pads. The conductive contacts 536 may be electrically coupled with the interconnect structures 528 and configured to route the electrical signals of the transistor(s) 540 to external devices. For example, solder bonds may be formed on the one or more conductive contacts 536 to mechanically and/or electrically couple an integrated circuit die including the integrated circuit 500 with another component (e.g., a printed circuit board). The integrated circuit 500 may include additional or alternate structures to route the electrical signals from the interconnect layers 506-510; for example, the conductive contacts 536 may include other analogous features (e.g., posts) that route the electrical signals to external components.

In some embodiments in which the integrated circuit 500 is a double-sided die, the integrated circuit 500 may include another metallization stack (not shown) on the opposite side of the device layer(s) 504. This metallization stack may include multiple interconnect layers as discussed above with reference to the interconnect layers 506-510, to provide electrically conductive paths (e.g., including conductive lines and vias) between the device layer(s) 504 and additional conductive contacts (not shown) on the opposite side of the integrated circuit 500 from the conductive contacts 536.

In other embodiments in which the integrated circuit 500 is a double-sided die, the integrated circuit 500 may include one or more through-silicon vias (TSVs) through the die substrate 502; these TSVs may make contact with the device layer(s) 504, and may provide electrically conductive paths between the device layer(s) 504 and additional conductive contacts (not shown) on the opposite side of the integrated circuit 500 from the conductive contacts 536. In some embodiments, TSVs extending through the substrate can be used for routing power and ground signals from conductive contacts on the opposite side of the integrated circuit 500 from the conductive contacts 536 to the transistors 540 and any other components integrated into the die with the integrated circuit 500, and the metallization stack 519 can be used to route I/O signals from the conductive contacts 536 to transistors 540 and any other components integrated into the die with the integrated circuit 500.

Multiple integrated circuits 500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

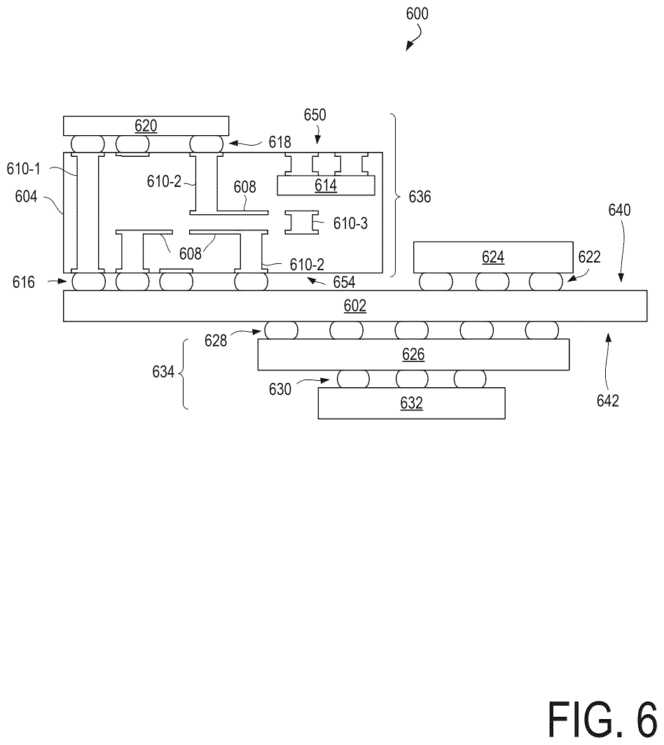

FIG. 6 is a cross-sectional side view of a microelectronic assembly 600 that may include any of the embodiments disclosed herein. The microelectronic assembly 600 includes multiple integrated circuit components disposed on a circuit board 602 (which may be a motherboard, system board, mainboard, etc.). The microelectronic assembly 600 may include components disposed on a first face 640 of the circuit board 602 and an opposing second face 642 of the circuit board 602; generally, components may be disposed on one or both faces 640 and 642.

In some embodiments, the circuit board 602 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 602. In other embodiments, the circuit board 602 may be a non-PCB substrate. The microelectronic assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 636 may include an integrated circuit component 620 coupled to an interposer 604 by coupling components 618. The coupling components 618 may take any suitable form for the application, such as the forms discussed above with reference to the coupling components 616. Although a single integrated circuit component 620 is shown in FIG. 6, multiple integrated circuit components may be coupled to the interposer 604; indeed, additional interposers may be coupled to the interposer 604. The interposer 604 may provide an intervening substrate used to bridge the circuit board 602 and the integrated circuit component 620.

The integrated circuit component 620 may be a packaged or unpackaged integrated circuit component that includes one or more integrated circuit dies (e.g., the die 402 of FIG. 4, the integrated circuit 500 of FIG. 5) and/or one or more other suitable components.

The unpackaged integrated circuit component 620 comprises solder bumps attached to contacts on the die. The solder bumps allow the die to be directly attached to the interposer 604. In embodiments where the integrated circuit component 620 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 604 may spread connections to a wider pitch or reroute a connection to a different connection. For example, the interposer 604 may couple the integrated circuit component 620 to a set of ball grid array (BGA) conductive contacts of the coupling components 616 for coupling to the circuit board 602. In the embodiment illustrated in FIG. 6, the integrated circuit component 620 and the circuit board 602 are attached to opposing sides of the interposer 604; in other embodiments, the integrated circuit component 620 and the circuit board 602 may be attached to a same side of the interposer 604. In some embodiments, three or more components may be interconnected by way of the interposer 604.

In some embodiments, the interposer 604 may be formed as a PCB, including multiple metal layers separated from one another by layers of dielectric material and interconnected by electrically conductive vias. In some embodiments, the interposer 604 may be formed of an epoxy resin, a fiberglass-reinforced epoxy resin, an epoxy resin with inorganic fillers, a ceramic material, or a polymer material such as polyimide. In some embodiments, the interposer 604 may be formed of alternate rigid or flexible materials that may include the same materials described above for use in a semiconductor substrate, such as silicon, germanium, and other group III-V and group IV materials. The interposer 604 may include metal interconnects 608 and vias 610, including but not limited to through hole vias 610-1 (that extend from a first face 650 of the interposer 604 to a second face 654 of the interposer 604), blind vias 610-2 (that extend from the first or second faces 650 or 654 of the interposer 604 to an internal metal layer), and buried vias 610-3 (that connect internal metal layers).

In some embodiments, the interposer 604 can comprise a silicon interposer. Through-silicon vias (TSV) extending through the silicon interposer can connect connections on the first face of a silicon interposer to an opposing second face of the silicon interposer. In some embodiments, an interposer 604 comprising a silicon interposer can further comprise one or more routing layers to route connections on a first face of the interposer 604 to an opposing second face of the interposer 604.

The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art.

The integrated circuit assembly 600 may include an integrated circuit component 624 coupled to the first face 640 of the circuit board 602 by coupling components 622. The coupling components 622 may take the form of any of the embodiments discussed above with reference to the coupling components 616, and the integrated circuit component 624 may take the form of any of the embodiments discussed above with reference to the integrated circuit component 620.

The integrated circuit assembly 600 illustrated in FIG. 6 includes a package-on-package structure 634 coupled to the second face 642 of the circuit board 602 by coupling components 628. The package-on-package structure 634 may include an integrated circuit component 626 and an integrated circuit component 632 coupled together by coupling components 630 such that the integrated circuit component 626 is disposed between the circuit board 602 and the integrated circuit component 632. The coupling components 628 and 630 may take the form of any of the embodiments of the coupling components 616 discussed above, and the integrated circuit components 626 and 632 may take the form of any of the embodiments of the integrated circuit component 620 discussed above. The package-on-package structure 634 may be configured in accordance with any of the package-on-package structures known in the art.

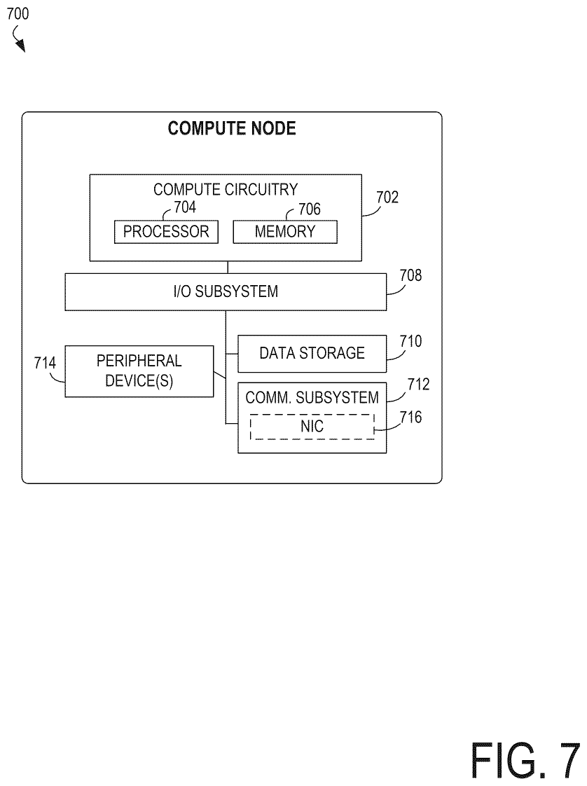

Disclosed embodiments may be implemented in a compute node. In the simplified example depicted in FIG. 7, a compute node 700 includes a compute engine (referred to herein as “compute circuitry”) 702, an input/output (I/O) subsystem 708, data storage 710, a communication circuitry subsystem 712, and, optionally, one or more peripheral devices 714. With respect to the present example, the compute node 700 or compute circuitry 702 may perform the operations and tasks attributed to the system 101. In other examples, respective compute nodes 700 may include other or additional components, such as those typically found in a computer (e.g., a display, peripheral devices, etc.). Additionally, in some examples, one or more of the illustrative components may be incorporated in, or otherwise form a portion of, another component.

In some examples, the compute node 700 may be embodied as a single device such as an integrated circuit, an embedded system, a field-programmable gate array (FPGA), a system-on-a-chip (SOC), or another integrated system or device. In the illustrative example, the compute node 700 includes or is embodied as a processor 704 and a memory 706. The processor 704 may be embodied as any type of processor capable of performing the functions described herein (e.g., executing compile functions and executing an application). For example, the processor 704 may be embodied as a multi-core processor(s), a microcontroller, a processing unit, a specialized or special purpose processing unit, or other processor or processing/controlling circuit.

In some examples, the processor 704 may be embodied as, include, or be coupled to an FPGA, an application specific integrated circuit (ASIC), reconfigurable hardware or hardware circuitry, or other specialized hardware to facilitate performance of the functions described herein. Also in some examples, the processor 704 may be embodied as a specialized x-processing unit (xPU) also known as a data processing unit (DPU), infrastructure processing unit (IPU), or network processing unit (NPU). Such an xPU may be embodied as a standalone circuit or circuit package, integrated within an SOC, or integrated with networking circuitry (e.g., in a SmartNIC, or enhanced SmartNIC), acceleration circuitry, storage devices, or AI hardware (e.g., GPUs or programmed FPGAs). Such an xPU may be designed to receive programming to process one or more data streams and perform specific tasks and actions for the data streams (such as hosting microservices, performing service management or orchestration, organizing, or managing server or data center hardware, managing service meshes, or collecting and distributing telemetry), outside of the CPU or general-purpose processing hardware. However, it will be understood that an xPU, a SOC, a CPU, and other variations of the processor 704 may work in coordination with each other to execute many types of operations and instructions within and on behalf of the compute node 700.

The memory 706 may be embodied as any type of volatile (e.g., dynamic random-access memory (DRAM), etc.) or non-volatile memory or data storage capable of performing the functions described herein. Volatile memory may be a storage medium that requires power to maintain the state of data stored by the medium. Non-limiting examples of volatile memory may include various types of random-access memory (RAM), such as DRAM or static random-access memory (SRAM). One type of DRAM that may be used in a memory module is synchronous dynamic random-access memory (SDRAM).

In an example, the memory device is a block addressable memory device, such as those based on NAND or NOR technologies. A memory device may also include a three-dimensional crosspoint memory device (e.g., Intel® 3D XPoint™ memory), or other byte addressable write-in-place nonvolatile memory devices. The memory device may refer to the die itself and/or to a packaged memory product. In some examples, 3D crosspoint memory (e.g., Intel® 3D XPoint™ memory) may comprise a transistor-less stackable cross point architecture in which memory cells sit at the intersection of word lines and bit lines and are individually addressable and in which bit storage is based on a change in bulk resistance. In some examples, all or a portion of the memory 706 may be integrated into the processor 704. The memory 706 may store various software and data used during operation such as one or more applications, data operated on by the application(s), libraries, and drivers.

The compute circuitry 702 is communicatively coupled to other components of the compute node 700 via the I/O subsystem 708, which may be embodied as circuitry and/or components to facilitate input/output operations with the compute circuitry 702 (e.g., with the processor 704 and/or the main memory 706) and other components of the compute circuitry 702. For example, the I/O subsystem 708 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some examples, the I/O subsystem 708 may form a portion of a system-on-a-chip (SoC) and be incorporated, along with one or more of the processor 704, the memory 706, and other components of the compute circuitry 702, into the compute circuitry 702.

The one or more illustrative data storage devices 710 may be embodied as any type of devices configured for short-term or long-term storage of data such as, for example, memory devices and circuits, memory cards, hard disk drives, solid-state drives, or other data storage devices. Individual data storage devices 710 may include a system partition that stores data and firmware code for the data storage device 710. Individual data storage devices 710 may also include one or more operating system partitions that store data files and executables for operating systems depending on, for example, the type of compute node 700.

The communication subsystem 712 may be embodied as any communication circuit, device, transceiver circuit, or collection thereof, capable of enabling communications over a network between the compute circuitry 702 and another computing device (e.g., an edge gateway of an implementing edge computing system).

The communication subsystem 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication subsystem 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication subsystem 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication subsystem 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication subsystem 712 may operate in accordance with other wireless protocols in other embodiments. The communication subsystem 712 may include an antenna to facilitate wireless communications and/or to receive other wireless communications (such as AM or FM radio transmissions).

In some embodiments, the communication subsystem 712 may manage wired communications, such as electrical, optical, or any other suitable communication protocols (e.g., IEEE 802.3 Ethernet standards). As noted above, the communication subsystem 712 may include multiple communication components. For instance, a first communication subsystem 712 may be dedicated to shorter-range wireless communications such as Wi-Fi or Bluetooth, and a second communication subsystem 712 may be dedicated to longer-range wireless communications such as global positioning system (GPS), EDGE, GPRS, CDMA, WiMAX, LTE, EV-DO, or others. In some embodiments, a first communication subsystem 712 may be dedicated to wireless communications, and a second communication subsystem 712 may be dedicated to wired communications.

The illustrative communication subsystem 712 includes an optional network interface controller (NIC) 720, which may also be referred to as a host fabric interface (HFI). The NIC 720 may be embodied as one or more add-in-boards, daughter cards, network interface cards, controller chips, chipsets, or other devices that may be used by the compute node 700 to connect with another computing device (e.g., an edge gateway node). In some examples, the NIC 720 may be embodied as part of a system-on-a-chip (SoC) that includes one or more processors or included on a multichip package that also contains one or more processors. In some examples, the NIC 720 may include a local processor (not shown) and/or a local memory (not shown) that are both local to the NIC 720. In such examples, the local processor of the NIC 720 may be capable of performing one or more of the functions of the compute circuitry 702 described herein. Additionally, or alternatively, in such examples, the local memory of the NIC 720 may be integrated into one or more components of the client compute node at the board level, socket level, chip level, and/or other levels.

Additionally, in some examples, a respective compute node 700 may include one or more peripheral devices 714. Such peripheral devices 714 may include any type of peripheral device found in a computing device or server such as audio input devices, a display, other input/output devices, interface devices, and/or other peripheral devices, depending on the particular type of the compute node 700. In further examples, the compute node 700 may be embodied by a respective edge compute node (whether a client, gateway, or aggregation node) in an edge computing system or like forms of appliances, computers, subsystems, circuitry, or other components.

In other examples, the compute node 700 may be embodied as any type of device or collection of devices capable of performing various compute functions. Respective compute nodes 700 may be embodied as a type of device, appliance, computer, or other “thing” capable of communicating with other compute nodes that may be edge, networking, or endpoint components. For example, a compute node may be embodied as a personal computer, server, smartphone, a mobile computing device, a smart appliance, smart camera, an in-vehicle compute system (e.g., a navigation system), a weatherproof or weather-sealed computing appliance, a self-contained device within an outer case, shell, etc., or other device or system capable of performing the described functions.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed aspects of the present disclosure. Various changes can be made in the function and arrangement of elements without departing from the scope of the disclosure as set forth in the appended claims and the legal equivalents thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

Additionally, theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

As used herein, phrases such as “embodiments,” “an aspect of the present disclosure,” “various aspects of the present disclosure,” “some aspects of the present disclosure,” and the like, indicate that some aspects of the present disclosure may have some, all, or none of the features described for other aspects of the present disclosure. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” can mean any combination of the listed terms. For example, the phrase “at least one of A, B and C” can mean A; B; C; A and B; A and C; B and C; or A, B, and C. Similarly, as used in this application and the claims, a list of items joined by the term “one or more of” can mean any combination of the listed terms. For example, the phrase “one or more of A, B and C” can mean A; B; C; A and B; A and C; B and C; or A, B, and C.

The following Examples pertain to additional aspects of the present disclosure of technologies disclosed herein.

Example 1 is a method comprising: accessing a library comprising a plurality of standard cells, wherein the library is characterized on a foundry process node and process node revision; for individual ones of the plurality of standard cells, performing a geometric analysis on said individual ones of the plurality of standard cells; identifying one or more potential defects based on the geometric analysis; in response to determining a potential defect in an individual standard cell, identifying the individual standard cell as a potentially defective standard cell and implementing a defect injection process; and generating simulated yield information for the library on the foundry process node and the process node revision based on implementation of the defect injection process.

Example 2 includes the subject matter of Example 1, further comprising: accessing silicon failure analysis data representing a plurality of test chips designed with the library; and generating an inferred failure rate for the individual standard cells of the plurality of standard cells, as a function of the silicon failure analysis and the simulated yield information.

Example 3 includes the subject matter of Example 2, further comprising: accessing new silicon failure analysis data representing a different plurality of test chips designed with the library; and revising the inferred failure rate for the individual standard cells of the plurality of standard cells based at least in part on the new silicon failure analysis data.

Example 4 includes the subject matter of Example 3, wherein revising the simulated yield information is performed by a machine learning model.

Example 5 includes the subject matter of Example 2, wherein the library is a first library, the process node revision is a first process node revision, and further comprising: obtaining a second library comprising the plurality of standard cells, wherein the second library is characterized on the foundry process node and a second process node revision; and generating a second inferred failure rate for the individual standard cells in the second library based at least in part on the inferred failure rate.

Example 6 includes the subject matter of Example 2, wherein the library is a first library, the foundry process node is a first foundry process node, the process node revision is a first process node revision, and further comprising: obtaining a second library comprising the plurality of standard cells, wherein the second library is characterized on a second foundry process node and a second process node revision; and generating a second inferred failure rate for the individual standard cells in the second library based at least in part on the inferred failure rate.

Example 7 includes the subject matter of Example 1, wherein potential defects comprise opens and shorts.

Example 8 includes the subject matter of Example 1, wherein performing the geometric analysis comprises processing layout and margin information identify locations that are vulnerable to an open or a short.

Example 9 includes the subject matter of Example 1, wherein implementing the defect injection process comprises revising the potentially defective standard cell to include an open or a short.

Example 10 is an apparatus, comprising: circuitry to: reference a library comprising a plurality of standard cells; and create a synthesized product chip based on the library; wherein the library is characterized on a foundry process node and process node revision; wherein the synthesized product chip reflects simulated yield information for the library on the foundry process node and the process node revision based on implementation of a defect injection process.

Example 11 includes the subject matter of Example 10, wherein the circuitry is further to: for individual ones of the plurality of standard cells, perform a geometric analysis on said individual ones of the plurality of standard cells; identify one or more potential defects based on the geometric analysis; in response to determining a potential defect in an individual standard cell, identify the individual standard cell as a potentially defective standard cell and implement a defect injection process; and generate the simulated yield information for the library on the foundry process node and the process node revision based on the defect injection process.

Example 12 includes the subject matter of Example 10, wherein the circuitry is further to: access silicon failure analysis data representing a plurality of test chips designed with the library; and generate an inferred failure rate for individual standard cells of the plurality of standard cells, as a function of the silicon failure analysis and the simulated yield information.

Example 13 includes the subject matter of Example 12, wherein the circuitry is further to: access new silicon failure analysis data representing a different plurality of test chips designed with the library; and revise the inferred failure rate for the individual standard cells of the plurality of standard cells based at least in part on the new silicon failure analysis data.

Example 14 includes the subject matter of Example 13, wherein the circuitry comprises a machine learning model.

Example 15 includes the subject matter of Example 12, wherein the library is a first library, the process node revision is a first process node revision, and wherein the circuitry is further to: obtain a second library comprising the plurality of standard cells, wherein the second library is characterized on the foundry process node and a second process node revision; and generate a second inferred failure rate for the individual standard cells in the second library based at least in part on the inferred failure rate.

Example 16 includes the subject matter of Example 12, wherein the library is a first library, the foundry process node is a first foundry process node, the process node revision is a first process node revision, and wherein the circuitry is further to: obtain a second library comprising the plurality of standard cells, wherein the second library is characterized on a second foundry process node and a second process node revision; and generate a second inferred failure rate for the individual standard cells in the second library based at least in part on the inferred failure rate.

Example 17 includes the subject matter of Example 11, wherein potential defects comprise opens and shorts.

Example 18 includes the subject matter of Example 11, wherein the circuitry is further to process layout and margin information to identify locations that are vulnerable to an open or a short.

Example 19 includes the subject matter of Example 18, wherein the circuitry is further to revise the potentially defective standard cell to include the open or the short.

Example 20 is one or more computer-readable storage media storing computer-executable instructions which when executed by a processor cause the processor to perform a method, the method comprising: accessing a library comprising a plurality of standard cells, wherein the library is characterized on a foundry process node and process node revision; for individual ones of the plurality of standard cells, performing a geometric analysis on said individual ones of the plurality of standard cells; identifying one or more potential defects based on the geometric analysis; in response to determining a potential defect in an individual standard cell, identifying the individual standard cell as a potentially defective standard cell and implementing a defect injection process; and generating simulated yield information for the library on the foundry process node and the process node revision based on implementation of the defect injection process.

Example 21 includes the subject matter of Example 20, wherein the method further comprises: accessing silicon failure analysis data representing a plurality of test chips designed with the library; and generating an inferred failure rate for the individual standard cells of the plurality of standard cells, as a function of the silicon failure analysis and the simulated yield information.

Example 22 includes the subject matter of Example 21, wherein the method further comprises: accessing new silicon failure analysis data representing a different plurality of test chips designed with the library; and revising the inferred failure rate for the individual standard cells of the plurality of standard cells based at least in part on the new silicon failure analysis data.

Example 23 includes the subject matter of Example 22, wherein revising the simulated yield information is performed by a machine learning model.

Example 24 includes the subject matter of Example 21, wherein the library is a first library, the process node revision is a first process node revision, and wherein the method further comprises: obtaining a second library comprising the plurality of standard cells, wherein the second library is characterized on the foundry process node and a second process node revision; and generating a second inferred failure rate for the individual standard cells in the second library based at least in part on the inferred failure rate.

Example 25 includes the subject matter of Example 21, wherein the library is a first library, the foundry process node is a first foundry process node, the process node revision is a first process node revision, and wherein the method further comprises: obtaining a second library comprising the plurality of standard cells, wherein the second library is characterized on a second foundry process node and a second process node revision; and generating a second inferred failure rate for the individual standard cells in the second library based at least in part on the inferred failure rate.

Example 26 includes the subject matter of Example 21, wherein potential defects comprise opens and shorts.

Example 27 includes the subject matter of Example 21, wherein performing the geometric analysis comprises processing layout and margin information identify locations that are vulnerable to an open or a short.

Example 28 includes the subject matter of Example 21, wherein the method further comprises revising the potentially defective standard cell to include an open or a short.

What is claimed is:

1. A method comprising:
accessing a library comprising a plurality of standard cells, wherein the library is characterized on a foundry process node and process node revision;
for individual ones of the plurality of standard cells, performing a geometric analysis on said individual ones of the plurality of standard cells;
identifying one or more potential defects based on the geometric analysis;
in response to determining a potential defect in an individual standard cell, identifying the individual standard cell as a potentially defective standard cell and implementing a defect injection process; and
generating simulated yield information for the library on the foundry process node and the process node revision based on implementation of the defect injection process.

2. The method of claim 1, further comprising:
accessing silicon failure analysis data representing a plurality of test chips designed with the library; and
generating an inferred failure rate for the individual standard cells of the plurality of standard cells, as a function of the silicon failure analysis and the simulated yield information.

3. The method of claim 2, further comprising:
accessing new silicon failure analysis data representing a different plurality of test chips designed with the library; and
revising the inferred failure rate for the individual standard cells of the plurality of standard cells based at least in part on the new silicon failure analysis data.

4. The method of claim 3, wherein revising the simulated yield information is performed by a machine learning model.

5. The method of claim 2, wherein the library is a first library, the process node revision is a first process node revision, and further comprising:
accessing a second library comprising the plurality of standard cells, wherein the second library is characterized on the foundry process node and a second process node revision; and
generating a second inferred failure rate for the individual standard cells in the second library based at least in part on the inferred failure rate.

6. The method of claim 2, wherein the library is a first library, the foundry process node is a first foundry process node, the process node revision is a first process node revision, and further comprising:
accessing a second library comprising the plurality of standard cells, wherein the second library is characterized on a second foundry process node and a second process node revision; and
generating a second inferred failure rate for the individual standard cells in the second library based at least in part on the inferred failure rate.

7. The method of claim 1, wherein potential defects comprise opens and shorts.

8. The method of claim 1, wherein performing the geometric analysis comprises processing layout and margin information identify locations that are vulnerable to an open or a short.

9. The method of claim 1, wherein implementing the defect injection process comprises revising the potentially defective standard cell to include an open or a short.

10. An apparatus, comprising:
circuitry to:
reference a library comprising a plurality of standard cells;
create a synthesized product chip based on the library; and
wherein the library is characterized on a foundry process node and process node revision;
wherein the synthesized product chip reflects simulated yield information for the library on the foundry process node and the process node revision based on implementation of a defect injection process.

11. The apparatus of claim 10, wherein the circuitry is further to:
for individual ones of the plurality of standard cells, perform a geometric analysis on said individual ones of the plurality of standard cells;
identify one or more potential defects based on the geometric analysis;
in response to determining a potential defect in an individual standard cell, identify the individual standard cell as a potentially defective standard cell and implement a defect injection process; and
generate the simulated yield information for the library on the foundry process node and the process node revision based on the defect injection process.

12. The apparatus of claim 10, wherein the circuitry is further to:
access silicon failure analysis data representing a plurality of test chips designed with the library; and
generate an inferred failure rate for individual standard cells of the plurality of standard cells, as a function of the silicon failure analysis and the simulated yield information.

13. The apparatus of claim 12, wherein the circuitry is further to:
access new silicon failure analysis data representing a different plurality of test chips designed with the library; and
revise the inferred failure rate for the individual standard cells of the plurality of standard cells based at least in part on the new silicon failure analysis data.

14. One or more computer-readable storage media storing computer-executable instructions which when executed by a processor cause the processor to perform a method, the method comprising:
accessing a library comprising a plurality of standard cells, wherein the library is characterized on a foundry process node and process node revision;
for individual ones of the plurality of standard cells, performing a geometric analysis on said individual ones of the plurality of standard cells;
identifying one or more potential defects based on the geometric analysis;
in response to determining a potential defect in an individual standard cell, identifying the individual standard cell as a potentially defective standard cell and implementing a defect injection process; and
generating simulated yield information for the library on the foundry process node and the process node revision based on implementation of the defect injection process.

15. The one or more computer-readable storage media of claim 14, wherein the method further comprises:
accessing silicon failure analysis data representing a plurality of test chips designed with the library; and
generating an inferred failure rate for the individual standard cells of the plurality of standard cells, as a function of the silicon failure analysis and the simulated yield information.

16. The one or more computer-readable storage media of claim 15, wherein the method further comprises:
accessing new silicon failure analysis data representing a different plurality of test chips designed with the library; and
revising the inferred failure rate for the individual standard cells of the plurality of standard cells based at least in part on the new silicon failure analysis data.

17. The one or more computer-readable storage media of claim 16, wherein revising the simulated yield information is performed by a machine learning model.

18. The one or more computer-readable storage media of claim 15, wherein the library is a first library, the process node revision is a first process node revision, and wherein the method further comprises:
accessing a second library comprising the plurality of standard cells, wherein the second library is characterized on the foundry process node and a second process node revision; and
generating a second inferred failure rate for the individual standard cells in the second library based at least in part on the inferred failure rate.

19. The one or more computer-readable storage media of claim 15, wherein the library is a first library, the foundry process node is a first foundry process node, the process node revision is a first process node revision, and wherein the method further comprises:
accessing a second library comprising the plurality of standard cells, wherein the second library is characterized on a second foundry process node and a second process node revision; and
generating a second inferred failure rate for the individual standard cells in the second library based at least in part on the inferred failure rate.

20. The one or more computer-readable storage media of claim 15, wherein performing the geometric analysis comprises processing layout and margin information identify locations that are vulnerable to an open or a short; and wherein the method further comprises revising the potentially defective standard cell to include the open or the short.
